(19) United States
(12) Patent Application Publication
(10) Pub. No.: US 2026/0231313 A1
(43) Pub. Date: Aug. 6, 2026

(54) LITHOGRAPHIC APPARATUS, METHOD OF INCREASING PLASMA CONCENTRATION, AND METHOD OF MANUFACTURING DEVICES

(71) Applicant: ASML Netherlands B.V., Veldhoven (NL)

(72) Inventors: Ernst GALUTSCHEK, Veldhoven (NL); Andrea JAGODAR, Eindhoven (NL); Ruud Martinus VAN DER HORST, Helmond (NL); Andrey NIKIPELOV, Eindhoven (NL); Paul JANSEN, Eindhoven (NL); Igor MILOV, s' Hertogenbosch (NL)

(73) Assignee: ASML Netherlands B.V., Veldhoven (NL)

(21) Appl. No.: 19/152,845

(22) PCT Filed: Feb. 12, 2024
(86) PCT No.: PCT/EP2024/053466

§ 371 Date: Jul. 31, 2025

(30) Foreign Application Priority Data
Feb. 20, 2023 (EP) 23157599.4

(51) Int. Cl. H05G 2/00; G03F 7/00; G03F 7/20

(52) U.S. Cl. CPC H05G 2/007; G03F 7/2004; G03F 7/70033; G03F 7/70116; G03F 7/706847; G03F 7/70933

(57) ABSTRACT

A lithographic apparatus comprising an enclosure, a microwave generator, and a magnetic source. The enclosure can define an environment, wherein the environment encompasses a surface (402), wherein the enclosure is configured to contain plasma. The microwave generator can be configured to provide microwave radiation (411) into the enclosure. The magnetic source can be configured to generate a magnetic field adjacent the surface which, together with the microwave radiation, generates plasma by electron cyclotron resonance, thereby increasing the concentration of plasma adjacent the surface.

### FIELD

The present invention relates to lithographic apparatuses, particularly extreme ultraviolet (EUV) lithographic apparatuses.

### BACKGROUND

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, may be used to generate a circuit pattern to be formed on an individual layer of the IC. This pattern can be transferred onto a target portion (e.g., comprising part of, one, or several dies) on a substrate (e.g., a silicon wafer). Transfer of the pattern is typically via imaging onto a layer of radiation-sensitive material (resist) provided on the substrate. In general, a single substrate will contain a network of adjacent target portions that are successively patterned.

Lithography is widely recognized as one of the key steps in the manufacture of ICs and other devices and/or structures. However, as the dimensions of features made using lithography become smaller, lithography is becoming a more critical factor for enabling miniature IC or other devices and/or structures to be manufactured.

A theoretical estimate of the limits of pattern printing can be given by the Rayleigh criterion for resolution as shown in equation (1):

$$C D = {k}_{1} * \frac{λ}{N A} \qquad ( 1 )$$

where λ is the wavelength of the radiation used, NA is the numerical aperture of the projection system used to print the pattern, k₁ is a process-dependent adjustment factor, also called the Rayleigh constant, and CD is the feature size (or critical dimension) of the printed feature. It follows from Equation (1) that reduction of the minimum printable size of features can be obtained in three ways: by shortening the exposure wavelength λ, by increasing the numerical aperture NA or by decreasing the value of k₁.

In order to shorten the exposure wavelength and, thus, reduce the minimum printable size, it has been proposed to use an extreme ultraviolet (EUV) radiation source. EUV radiation is electromagnetic radiation having a wavelength within the range of 10-20 nm, for example within the range of 13-14 nm. It has further been proposed that EUV radiation with a wavelength of less than 10 nm could be used, for example within the range of 5-10 nm such as 6.7 nm or 6.8 nm. Such radiation is termed extreme ultraviolet radiation or soft x-ray radiation. Possible sources include, for example, laser-produced plasma sources, discharge plasma sources, or sources based on synchrotron radiation provided by an electron storage ring, or a free electron laser.

Once the EUV radiation has been generated, it is directed through the lithographic apparatus by a plurality of mirrors to a patterning surface of the patterning device, which imparts the desired pattern to the EUV radiation.

The EUV generation process may deposit residues on various surfaces of the lithographic apparatus such as tin from the EUV light source or hydrogen induced outgassing (HIO). Another example of residues is water, which may form on surfaces when the lithographic apparatus is brought out of a vacuum condition for e.g. maintenance. The presence of such residues may degrade the performance of the lithographic apparatus, for example when they are present on optical surfaces. Such residues can be removed by contact with hydrogen plasma, which ionizes the residues. However, depending on where the surface is located within the lithographic apparatus, it may be difficult to transport a sufficient supply of hydrogen plasma to the surface for removing the residues. As such, certain surfaces in the lithographic apparatus may be susceptible to residue accumulation.

In order to clean these surfaces, it may be necessary to shut down the lithographic apparatus for extended periods of time. However, this increases the downtime of the lithographic apparatus, and thus reduces the manufacturing throughput of the lithographic apparatus.

### SUMMARY OF THE INVENTION

An aim of the present invention is thus to provide a more effective technique of increasing a plasma concentration in a lithographic apparatus, which may be used for cleaning surfaces and other purposes.

Another aim of the present invention is to reduce the availability cost associated with cleaning operations of an EUV lithographic apparatus.

According to an aspect of the present invention, there is provided a lithographic apparatus comprising:
an enclosure defining an environment, wherein the environment encompasses a surface, wherein the enclosure is configured to contain plasma;
a microwave generator configured to provide microwave radiation into the enclosure;
a magnetic source configured to generate a magnetic field adjacent the surface which, together with the microwave radiation, generates additional plasma by electron cyclotron resonance, thereby increasing the concentration of plasma adjacent the surface.

According to another aspect of the present invention, there is provided a method comprising:
providing, by a microwave generator, microwave radiation into an enclosure, wherein the enclosure defines an environment in a lithographic apparatus, and the environment encompasses a surface; and
generating, by a magnetic source, a magnetic field adjacent the surface which, together with the microwave radiation, generates plasma by electron cyclotron resonance, thereby increasing the concentration of plasma adjacent the surface.

### BRIEF DESCRIPTION OF THE DRAWINGS

Embodiments of the invention will now be described, by way of example only, with reference to the accompanying schematic drawings, in which corresponding reference symbols indicate corresponding parts.

FIG. 1 schematically depicts a lithographic apparatus.

FIG. 2 schematically depicts a more detailed view of the lithographic apparatus.

FIG. 3 schematically depicts an EUV LPP source in accordance with an embodiment.

FIG. 4 schematically depicts an EUV LPP source in accordance with an embodiment.

FIG. 5 schematically depicts a MEMS device in accordance with an embodiment.

FIG. 6 schematically depicts an illuminator in accordance with an embodiment.

FIG. 7 schematically depicts a patterning device environment in accordance with an embodiment.

FIG. 8 schematically depicts providing microwave radiation into multiple environments, in accordance with an embodiment.

FIG. 9 schematically depicts a second magnetic source in accordance with an embodiment.

FIGS. 10a and 10b schematically depict enclosures with a plasma extractor in accordance with embodiments.

FIG. 11 schematically depicts an enclosure with multiple plasma extractors in accordance with an embodiment.

FIG. 12 schematically depicts a small-diameter enclosure with a plasma extractor in accordance with an embodiment.

FIG. 13 schematically depicts a microwave coupler which extends into an enclosure in accordance with an embodiment.

FIGS. 14a and 14b schematically depict an enclosure with a surrounding circular Halbach array in accordance with an embodiment.

The features shown in the Figures are not necessarily to scale, and the size and/or arrangement depicted is not limiting. It will be understood that the Figures include optional features which may not be essential to the invention. Furthermore, not all of the features of the apparatus are depicted in each of the figures, and the Figures may only show some of the components relevant for describing a particular feature.

### DETAILED DESCRIPTION

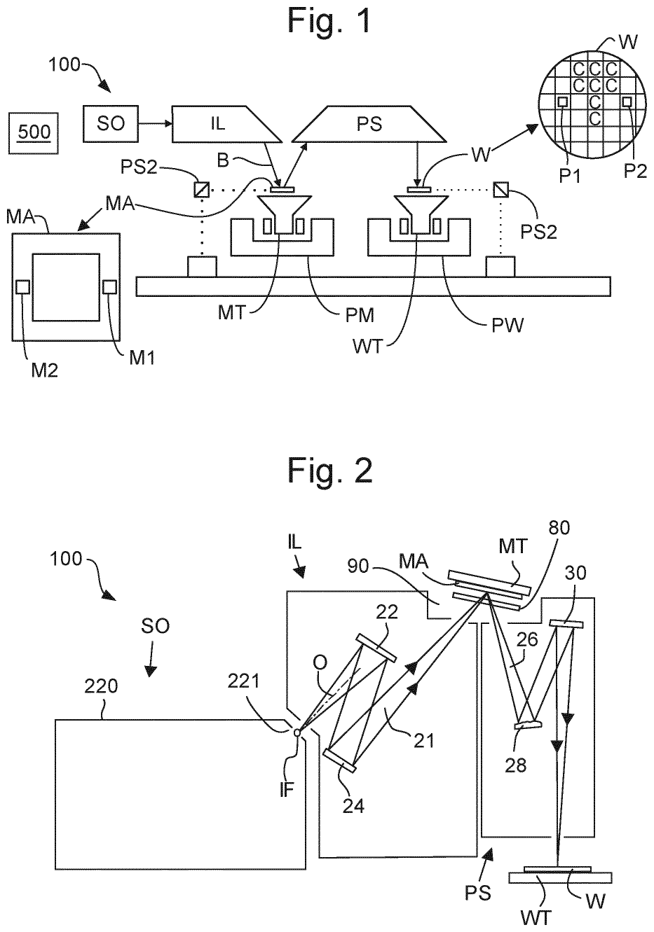

FIG. 1 schematically depicts a lithographic apparatus 100 including a radiation source SO according to one embodiment of the invention. The apparatus 100 comprises:
an illumination system (or illuminator) IL configured to condition a radiation beam B (e.g., EUV radiation).
a support structure (e.g., a mask table) MT constructed to support a patterning device (e.g., a mask or a reticle) MA and connected to a first positioner PM configured to accurately position the patterning device;
a substrate table (e.g., a wafer table) WT constructed to hold a substrate (e.g., a resist-coated wafer) W and connected to a second positioner PW configured to accurately position the substrate; and
a projection system (e.g., a reflective projection system) PS configured to project a pattern imparted to the radiation beam B by patterning device MA onto a target portion C (e.g., comprising one or more dies) of the substrate W.

The illumination system IL may include various types of optical components, such as refractive, reflective, magnetic, electromagnetic, electrostatic or other types of optical components, or any combination thereof, for directing, shaping, or controlling radiation.

The support structure MT holds the patterning device MA in a manner that depends on the orientation of the patterning device, the design of the lithographic apparatus, and other conditions, such as for example whether or not the patterning device is held in a vacuum environment. The support structure MT can use mechanical, vacuum, electrostatic or other clamping techniques to hold the patterning device MA. The support structure MT may be a frame or a table, for example, which may be fixed or movable as required. The support structure MT may ensure that the patterning device MA is at a desired position, for example with respect to the projection system PS.

The term “patterning device” should be broadly interpreted as referring to any device that can be used to impart a radiation beam B with a pattern in its cross-section such as to create a pattern in a target portion C of the substrate W. The pattern imparted to the radiation beam B may correspond to a particular functional layer in a device being created in the target portion C, such as an integrated circuit.

Examples of patterning devices include masks, programmable mirror arrays, and programmable liquid-crystal display (LCD) panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted so as to reflect an incoming radiation beam in different directions. The tilted mirrors impart a pattern in a radiation beam, which is reflected by the mirror matrix.

The projection system PS, like the illumination system IL, may include various types of optical components, such as refractive, reflective, magnetic, electromagnetic, electrostatic or other types of optical components, or any combination thereof, as appropriate for the exposure radiation being used, or for other factors such as the use of a vacuum. It may be desired to use a vacuum for EUV radiation since other gases may absorb too much radiation. A vacuum environment may therefore be provided to the whole beam path with the aid of a vacuum wall and vacuum pumps.

As here depicted, the lithographic apparatus 100 is of a reflective type (e.g., employing a reflective mask).

The lithographic apparatus 100 may be of a type having two (dual stage) or more substrate tables WT (and/or two or more support structures MT). In such a “multiple stage” lithographic apparatus the additional substrate tables WT (and/or the additional support structures MT) may be used in parallel, or preparatory steps may be carried out on one or more substrate tables WT (and/or one or more support structures MT) while one or more other substrate tables WT (and/or one or more other support structures MT) are being used for exposure.

Referring to FIG. 1, the illumination system IL receives an extreme ultraviolet radiation beam from the radiation source SO. The radiation source SO may be a laser produced plasma (LPP) source, a discharge produced plasma (DPP) source, a free electron laser (FEL) or any other radiation source that is capable of generating EUV radiation. Methods to produce EUV light include, but are not necessarily limited to, converting a material into a plasma state that has at least one element, e.g., xenon, lithium or tin, with one or more emission lines in the EUV range. In laser produced plasma (“LPP”), the required plasma can be produced by irradiating a fuel, such as a droplet, stream or cluster of material having the required line-emitting element, with a laser beam. The radiation source SO may be part of an EUV radiation system including a laser, not shown in FIG. 1, for providing the laser beam exciting the fuel. The resulting plasma emits output radiation, e.g., EUV radiation, which is collected using a radiation collector, disposed in the radiation source SO. The laser and the radiation source SO may be separate entities, for example when a CO₂ laser is used to provide the laser beam for fuel excitation.

In such cases, the laser is not considered to form part of the lithographic apparatus 100 and the radiation beam B is passed from the laser to the radiation source SO with the aid of a beam delivery system comprising, for example, suitable directing mirrors and/or a beam expander. In other cases the source may be an integral part of the radiation source SO, for example when the source is a discharge produced plasma EUV generator, often termed as a DPP source.

The illumination system IL may comprise an adjuster for adjusting the angular intensity distribution of the radiation beam. Generally, at least the outer and/or inner radial extent (commonly referred to as σ-outer and σ-inner, respectively) of the intensity distribution in a pupil plane of the illumination system IL can be adjusted. In addition, the illumination system IL may comprise various other components, such as facetted field and pupil mirror devices. The illumination system IL may be used to condition the radiation beam B, to have a desired uniformity and intensity distribution in its cross-section.

The radiation beam B is incident on the patterning device (e.g., mask) MA, which is held on the support structure (e.g., mask table) MT, and is patterned by the patterning device MA. After being reflected from the patterning device (e.g., mask) MA, the radiation beam B passes through the projection system PS, which focuses the radiation beam B onto a target portion C of the substrate W. With the aid of the second positioner PW and position sensor PS2 (e.g., an interferometric device, linear encoder or capacitive sensor), the substrate table WT can be moved accurately, e.g., so as to position different target portions C in the path of the radiation beam B. Similarly, the first positioner PM and another position sensor PS1 can be used to accurately position the patterning device (e.g., mask) MA with respect to the path of the radiation beam B. The patterning device (e.g., mask) MA and the substrate W may be aligned using mask alignment marks M1, M2 and substrate alignment marks P1, P2.

A controller 500 controls the overall operations of the lithographic apparatus 100 and in particular performs an operation process described further below. Controller 500 can be embodied as a suitably-programmed general purpose computer comprising a central processing unit, volatile and non-volatile storage means, one or more input and output devices such as a keyboard and screen, one or more network connections and one or more interfaces to the various parts of the lithographic apparatus 100. It will be appreciated that a one-to-one relationship between controlling computer and lithographic apparatus 100 is not necessary. In an embodiment of the invention one computer can control multiple lithographic apparatuses 100. In an embodiment of the invention, multiple networked computers can be used to control one lithographic apparatus 100. The controller 500 may also be configured to control one or more associated process devices and substrate handling devices in a lithocell or cluster of which the lithographic apparatus 100 forms a part. The controller 500 can also be configured to be subordinate to a supervisory control system of a lithocell or cluster and/or an overall control system of a fab.

FIG. 2 shows the lithographic apparatus 100 in more detail, including the radiation source SO, the illumination system IL, and the projection system PS. An EUV radiation emitting plasma may be formed by a plasma source. EUV radiation may be produced by a gas or vapour, for example Xe gas, Li vapour or Sn vapour in which the radiation emitting plasma is created to emit radiation in the EUV range of the electromagnetic spectrum. In an embodiment, a plasma of excited tin (Sn) is provided to produce EUV radiation.

The radiation source SO may include a radiation collector. Radiation that traverses the radiation collector can be focused in a virtual source point IF. The virtual source point IF is commonly referred to as the intermediate focus, and the radiation source SO is arranged such that the virtual source point IF is located at or near an opening 221 in the enclosing structure 220. The virtual source point IF is an image of the radiation emitting plasma.

Subsequently the radiation traverses the illumination system IL, which may include a facetted field mirror device 22 and a facetted pupil mirror device 24 arranged to provide a desired angular distribution of the unpatterned beam 21, at the patterning device MA, as well as a desired uniformity of radiation intensity at the patterning device MA. Upon reflection of the unpatterned beam 21 at the patterning device MA, held by the support structure MT, a patterned beam 26 is formed and the patterned beam 26 is imaged by the projection system PS via reflective elements 28, 30 onto a substrate W held by the substrate table WT. A pellicle 80 may be used to protect the patterning device from contaminants.

More elements than shown may generally be present in the illumination system IL and the projection system PS. Further, there may be more mirrors present than those shown in the Figures, for example there may be 1-6 additional reflective elements present in the projection system PS than shown in FIG. 2.

Alternatively, the radiation source SO may be part of an LPP radiation system.

As depicted in FIG. 1, in an embodiment the lithographic apparatus 100 comprises an illumination system IL and a projection system PS. The illumination system IL is configured to emit a radiation beam B. The projection system PS is separated from the substrate table WT by an intervening space. The projection system PS is configured to project a pattern imparted to the radiation beam B onto the substrate W. The pattern is for EUV radiation of the radiation beam B.

The substrate W may include previously formed patterns. Where this is the case, the lithographic apparatus 100 aligns the image, formed by the patterned EUV radiation beam B, with a pattern previously formed on the substrate W.

The space intervening between the projection system PS and the substrate table WT can be at least partially evacuated. The intervening space may be delimited at the location of the projection system PS by a solid surface from which the employed radiation is directed toward the substrate table WT.

Both the patterning device MA and support structure MT may be contained within a patterning device environment 90. The patterning device environment 90 may be separated from an external environment surrounding the lithographic apparatus 100 and/or other components within the lithographic apparatus such that gases and contaminant particles are substantially prevented from entering the patterning device environment 90.

The patterning device environment 90 may be partially evacuated of gas. That is, the pressure within the patterning device environment 90 may be less than ambient pressure. This is to limit the attenuation of EUV radiation as it travels through the patterning device environment 90. Even though the pressure within the patterning device 90 is less than ambient pressure, it is not a perfect vacuum, so gas particles are present in the patterning device environment 90. Likewise, a relative vacuum, i.e. a small amount of gas (e.g. hydrogen) at a pressure well below atmospheric pressure, may be provided in the radiation source SO, in the illumination system IL, and/or in the projection system PS.

As noted above, certain surfaces of a lithographic apparatus 100 may be prone to accumulate residues. For example, tin vapour resulting from EUV generation may be deposited onto certain surfaces of the lithographic apparatus 100. For another example, during a pump-down operation of the lithographic apparatus, during which the pressure within the lithographic apparatus rises from vacuum, water vapour may condense on certain surfaces of the lithographic apparatus 100. The presence of such residues may degrade the performance of the lithographic apparatus 100. In particular, the presence of residues on optical surfaces may reduce the reflectivity of the optical surfaces.

The present invention seeks to provide a technique of generating plasma by electron cyclotron resonance (ECR), which plasma may be used for removing these residues. ECR is a well-understood phenomenon whereby, in the presence of appropriate magnetic field and electromagnetic radiation, free electrons are excited by absorbing energy from the electromagnetic radiation. Generating plasma by ECR is well established and is widely used in a variety of technologies. For example, in some ECR devices, microwave radiation is injected directly into a source chamber, which may be fed with a metal vapour or other gas. Preferably the ionizers operate in the existing environment in the lithographic apparatus or other tools where it is implemented, for example in a hydrogen atmosphere without an additional gas supply. A magnetic coil surrounds the source chamber and creates a magnetic field within the source chamber. Microwave absorption occurs at locations in the magnetic field configuration where the field matches the conditions for resonant absorption by the electrons, resulting in the generation of plasma. The plasma is then ejected from the source chamber for further use. Besides plasma, also an electron beam or an ion beam may be alternatively generated using ECR generators, depending on the particular use case.

In theory, plasma generated by known ECR devices could be used, for example, to remove residues from surfaces within a lithographic apparatus 100, or to control the surface charge present on surfaces such as patterning device MA, or to control particle charge. However, in practice, given the complexity of the various components of a lithographic apparatus 100, there are generally severe space constraints which preclude placing such ECR devices at locations where they might be needed. The lack of space can be particularly severe in the vicinity of surfaces where the deposition of residues is most likely to occur. Additionally or alternatively, it may not be possible to place such ECR devices at the desired location due to obstruction of an optical path within the lithographic apparatus 100.

An inventive recognition made by the present inventors is that the microwave source and the magnetic source can be decoupled and still generate sufficient plasma in a lithographic apparatus 100. That is, unlike in certain known ECR devices where the microwave source and the magnetic source are closely coupled together, in a lithographic apparatus it is possible to position the microwave source far away from the magnetic source. As found by the inventors, this approach is particularly effective in a lithographic apparatus 100 due to the presence of plasma resulting from EUV generation.

For example, in the LPP device mentioned above, when EUV is generated by exciting tin vapour using a laser beam, a hydrogen plasma is also produced. The hydrogen plasma, which contains a mixture of free protons and free electrons, provides a base concentration of free electrons which can absorb energy from the microwave radiation by electron cyclotron resonance. The excited electrons can then interact with other particles, including residue particles deposited on certain surfaces of a lithographic apparatus 100 and hydrogen gas (H₂) present in the environment, which in turn creates even more plasma with further free electrons capable of absorbing energy from the microwave radiation. In other words, the presence of a base concentration of plasma resulting from EUV generation facilitates the ignition of plasma where appropriate microwave radiation and magnetic field is provided. More specifically, due to the presence of plasma resulting from EUV generation, a relatively low power and frequency (e.g. 2.45 GHz) of microwave radiation can be used to ignite the plasma, which may have the advantage of a readily available equipment. However, ignition of plasma may be easier at frequencies greater than 2.45 GHz. Higher frequencies may make the ignition of the plasma easier while less power is required and may allow operation without additional gas supply. Furthermore, microwaves of higher frequency can propagate trough smaller hollow waveguides (for example hollow waveguides for e.g. 2.45 GHz may be too large for applications in lithographic apparatuses or other tools where they are used), which enables the use of smaller devices. A simple device to implement according to the invention can be a hollow waveguide with several holes/apertures which can be seen as a ‘box’ having holes (like a multi aperture extraction system) and with permanent magnets ‘next’ to it, such that no biasing is required. Such arrangement may also provide that unconventional geometries (e.g. asymmetric devices) can be fitted into a limited space available. Hollow waveguides allow therefore unconventional plasma chamber shapes to fill the available space, which provides less stress on the material with larger plasma chamber within available space. Hollow waveguides make it also easier to use dielectric liners and cover the inside of the plasma chamber with dielectric surfaces. Additionally, the use of higher microwave frequencies may result in higher electron energies that makes it easier to ‘extract’ trough several holes/apertures in the waveguide of electrons having sufficient energy and current while using a low bias voltage or even without (zero) bias voltage. Finally, if an additional gas supply may be needed a ‘counterflow’ may easily be implemented with the use of hollow waveguides. Without the presence of the base concentration of plasma, ignition of the plasma may still be possible but may require a higher microwave power, or may require the frequency of the microwave to be substantially higher (e.g. greater than 2.45 GHz) and the magnetic field strength to be correspondingly higher. Once the plasma has been ignited, the plasma can be sustained with a further reduction of microwave power.

In certain known ECR devices, the microwave source and the magnetic source are closely coupled because of the absence of a sufficient base concentration of free electrons. Generally, in these known ECR devices, free electrons are initially present due to cosmic radiation, but the number of the free electrons generated in this way is small and random. Therefore, in known ECR devices, in order to ignite a plasma starting from these few initial free electrons, either a relatively high microwave power is needed, or a relatively high microwave frequency and correspondingly strong magnetic field are needed. In certain known ECR devices, particularly those which employ e.g. 2.45 GHz microwave radiation, in order to provide a sufficient microwave power, microwave radiation has to be injected directly from the microwave source to the location where the magnetic field is provided, hence the close integration of the magnetic source and the microwave source. This could in theory be related also to that longer wavelengths cannot propagate in too small “waveguides” or in small spaces and it is also more difficult to “focus” longer wavelength microwaves. In these known ECR devices, if the microwave source were to be separated from the magnetic field by a large distance, the microwave power generated by the microwave source would have to be increased dramatically in order to compensate for the drop in microwave power at the location where the magnetic field is provided. For this reason, in these known ECR devices, it is impractical to physically separate the microwave source from the magnetic source.

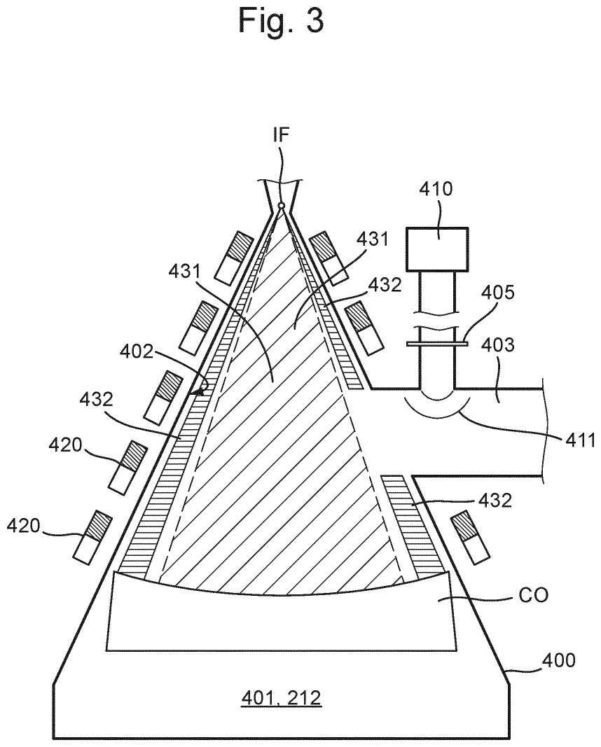

Referring now to FIGS. 3 to 7, in accordance with an embodiment of the present invention, there is disclosed a lithographic apparatus 100 comparing an enclosure 400, a microwave generator 410, and a magnetic source 420. The enclosure 400 defines an environment 401. As will be disclosed further below, in some embodiments, the environment 401 can be an environment within the lithographic apparatus 100 where plasma resulting from EUV generation is present. The environment 401 encompasses a surface 402, which may be a surface to be cleaned, or more generally a surface which may require exposure to plasma. The enclosure 400 may be configured to contain plasma, including a base concentration of plasma 431 resulting from EUV generation. As used herein, an “enclosure” need not be fluid-tight, and may have apertures and orifices through which fluids and or light may pass. The microwave generator 410 is located outside the environment 401, and is configured to provide microwave radiation 411 into the enclosure 400. As shown, the location at which microwave radiation 411 is introduced into the enclosure 400 may be physically distanced from the magnetic source 420. A microwave launcher (not shown) may be present at the point where the microwave radiation 411 is introduced into the enclosure 400. The microwave launcher may provide impedance matching for microwave radiation 411 entering the enclosure 400.

The magnetic source 420 is configured to generate a magnetic field adjacent the surface 402. Generally, because magnetic fields have a short range, the magnetic source 420 may be provided close to the surface 402 so that a relatively high strength of magnetic field is present close to the surface 402. The magnetic field adjacent the surface 402, together with the microwave radiation, generates additional plasma 432 by electron cyclotron resonance. As explained above, a pre-existing base concentration of plasma 431 resulting from EUV generation may exist and may lower the microwave power needed to ignite additional plasma 432 without requiring a high-frequency microwave radiation and a high-strength magnetic field, thereby making it possible to position the microwave generator 410 outside the environment 401. The generation of the additional plasma 432 increases the concentration of plasma adjacent the surface 402. The plasma may be used to remove residues on the surface 402. The plasma may also be used for other purposes.

The plasma may comprise hydrogen plasma, i.e. a mixture of free protons and free electrons. This may be true of the plasma 431 resulting from EUV generation, especially when EUV is generated by exciting a tin vapour. Similarly, the additional plasma 432 may also comprise hydrogen plasma, which may result from ionisation of hydrogen gas (H₂) present in the environment 401.

The enclosure 400 may be configured to contain hydrogen gas (H₂). This is because hydrogen gas may be present in many environments 401 within a lithographic apparatus 100. Compared with some conventional ECR devices, in the context of a lithographic apparatus 100, a dedicated gas feed into the enclosure 400 may not be necessary because there may already be enough hydrogen gas present in the environment 401 within the lithographic apparatus 100. Furthermore, an advantage of not including a dedicated gas feed (e.g. a hydrogen gas feed) is that plasma may be generated without raising the amount of hydrogen gas per volume space, so that a high transmission rate of EUV can be maintained. Specifically, the enclosure may be configured to contain the hydrogen gas so that the hydrogen gas does not reach the outside the enclosure 400. Hollow waveguides enable a ‘counterflow’ away from the orifices where the plasma/electrons/ions are extracted from. This may help to prevent particle contamination by suppressing transport of particles from the inside of the plasma generator to sensitive surfaces that are aimed to be kept clean by means of plasma, electron beam and/or ion beam.

As noted above, different kinds of residues may be found on the surface 402. For example, some of the tin vapour used in EUV generation may be deposited on the surface 402. For another example, the residues may comprise hydrogen-induced outgassing elements (e.g. tin, zinc, lead or sulphur). For another example, the residues may comprise water. Specifically, water may form when the lithographic apparatus 100 is brought out of vacuum for maintenance. When the vacuum is released, a monolayer of water may condense on the surface 402. When vacuum is subsequently restored during pump-down, most gasses such as hydrogen and nitrogen will be evacuated, but the water monolayer may remain adhered to the surface 402. The presence of water may have a deleterious effect, for example when it is irradiated by EUV. The EUV radiation can break water modules down into harmful particles, e.g. atomic oxygen. The plasma particles generated by electron cyclotron resonance may have enough kinetic energy to release the water molecules from the surface 402, so that they can be evacuated away from the environment 401 during pump-down.

Unlike certain known ECR devices, the present approach to plasma generation does not require a dedicated plasma chamber. In some ECR plasma generators that require no plasma chamber the plasma is generated next to the microwave coupler. Instead, herein the additional plasma 432 is generated directly at the location where it is required. More specifically, the location where the additional plasma 432 is generated can be controlled by placing a magnetic source 420 at an appropriate location, so that a magnetic field is generated adjacent the surface 402 where additional plasma 432 is required. The precise placement of the microwave generator 410 outside the environment may not be critical, so long as the microwave radiation 411 is provided into the enclosure 400 defining the environment 401 in which the surface 402 is located. Compared with a complete ECR device, the magnetic source 420 may be much more compact, and can be provided at locations within the lithographic apparatus even where space is limited. Furthermore, it may be possible to position the magnetic source 420 at the required location without obstructing optical paths. Furthermore, the magnetic source 420 may be relatively simple to integrate into the lithographic apparatus 100 as required. For example, since magnetic fields can penetrate some solid walls (unlike plasmas), the magnetic source 420 may be able to provide the required magnetic field through a wall of the enclosure 400, thereby avoiding creating extra orifices on the wall.

In addition, by leveraging the base concentration of plasma 431 resulting from EUV generation, the power and frequency of microwave radiation 411 and the strength of the magnetic field required to ignite, and subsequently sustain, the additional plasma 432 can be low.

As found by the present inventors, in one implementation, a short application of microwave radiation of around 1 ms to 100 ms was sufficient to ignite the additional plasma. Also, the power of the microwave radiation required for the ignition was comparable to the power level needed in known ECR devices for sustaining the plasma. For example, in one implementation, ignition of the additional plasma was achieved with a microwave power density of less than 1 W/cm³. In this implementation, once the additional plasma was ignited, it was possible to sustain the additional plasma using about 1/30th to 1/10th of the microwave power density needed for ignition. In other words, as found by the present inventors, even though the microwave generator 410 is located some distance away from the magnetic source 420, due to the presence of the base concentration of plasma 431 resulting from EUV generation, the microwave power required to ignite and sustain the generation of additional plasma 432 may be significantly (e.g. by an order of magnitude) lower than that required in certain known ECR devices.

The magnetic source 420 can be of any type provided that it can generate the requisite magnetic field. For example, the magnetic source 420 may comprise a permanent magnet, and/or an electromagnet. For example, the magnetic source 420 may be a neodymium magnet or a magnet made from any other magnetic material. In case the magnetic material is incompatible with the environment from the lithographic apparatus, optionally the magnet may be encapsuled with a protective coating. Such a coating may help to avoid degradation such as embrittlement induced by the hydrogen atmosphere. Preferably, the magnetic source 420 is a magnet made from a material which is compatible with the environment present in the lithographic apparatus. The use of a permanent magnet may simplify the implementation of the lithographic apparatus 100 because no electrical supply is necessary. Furthermore, the use of a permanent magnet may also be beneficial in terms of thermal management, because permanent magnets do not suffer from Joule heating.

As noted above, the magnetic source 420 may be placed in a location where the additional plasma 432 is required. In the simplest implementation, the magnetic source 420 may comprise a single permanent magnet or a single electromagnet. However, depending on the shape and size of the surface 402 requiring exposure to the additional plasma 432, it may be more appropriate to provide a magnetic source 420 comprising a plurality of permanent magnets and/or electromagnets. FIGS. 3 to 6 all depict arrangements in which a plurality of magnets are used to provide magnetic fields to a surface 402. It should be noted that, although the figures depict the magnetic source 420 using an symbol typically associated with permanent magnets, the magnetic source 420 may comprise one or more permanent magnet, or one or more electromagnet, or a combination of permanent magnets and electromagnets. By using a plurality of permanent magnets and/or electromagnets, a sufficient magnetic field may be generated adjacent the surface 402 even if it has a large area.

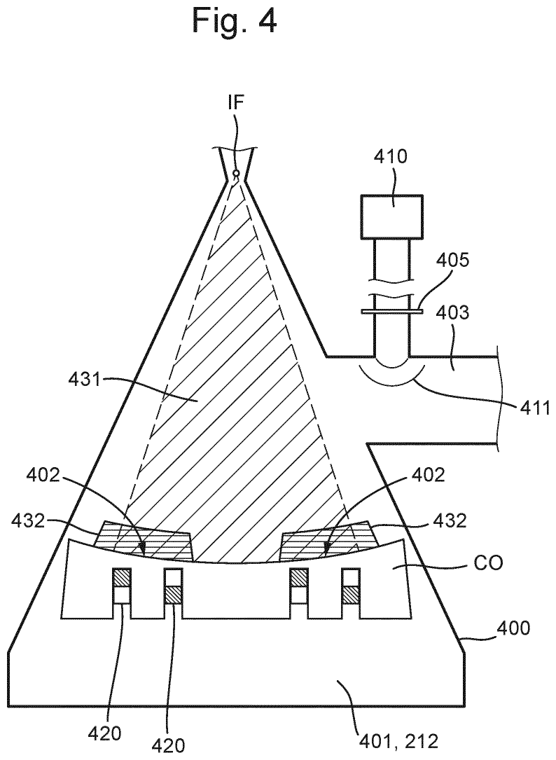

The magnetic source 420 may operate in the plasma 432 but may be shielded from the outside. For example, as shown in FIG. 4, the magnetic source 420 may be provided behind the optical surface of a collector mirror CO. Additionally or alternatively, the magnetic source 420 may be coated or encased. This may be advantageous because certain types of magnetic sources 420 are incompatible with the plasma 432, which may contain H+ ions, and/or gasses within the environment 401. For example, unless they are encapsulated with a protective coating neodymium magnets may be incompatible with hydrogen due to embrittlement.

In the example shown in FIG. 4, the magnetic source 420 may be located within the environment 401. However, as shown in FIG. 3, the magnetic source 420 may instead be located outside the enclosure 400. As a result, the plasma 432 may be separated from the magnetic source 420 by a wall of the enclosure 400. As such, the magnetic source 420 may be further protected from the plasma 432 and/or gasses within the environment 401.

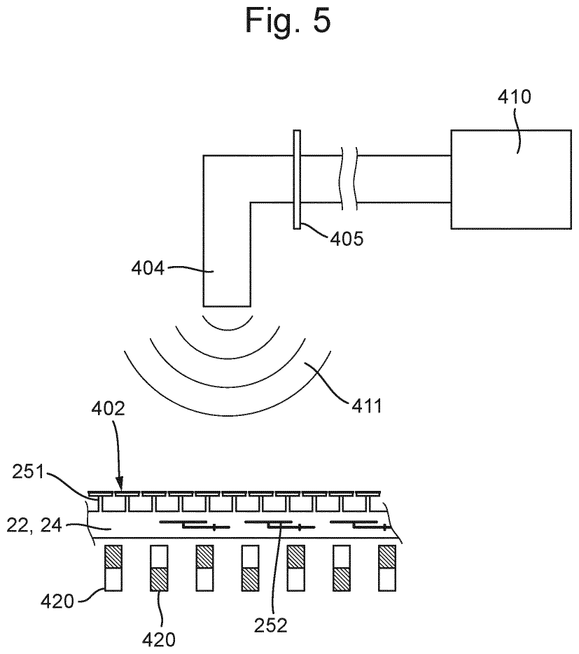

As noted above, the microwave generator 410 is located outside the environment 401, and the microwave generator 410 is configured to provide microwave radiation 411 into the enclosure 400 defining the environment 401. As shown in the example of FIG. 5, a waveguide 404 may be provided to guide the microwave radiation 411 form the microwave generator 410 into the enclosure 400. The use of a waveguide 404 may provide flexibility in the placement of the microwave generator 401 within the lithographic apparatus 100. In particular, the microwave generator 410 may be placed far away from the environment 401 and, due to the presence of the waveguide 404, microwave radiation may still be efficiently guided into the enclosure 400, and the microwave power may still be sufficient to ignite the plasma 432.

In particular, the waveguide 404 may be a hollow waveguide. The use of a hollow waveguide may enable a robust microwave launcher design because, in contrast to coaxial waveguides, the propagation of microwaves in a hollow waveguide does not require electrical isolation of the center conductor, which is relevant in the case that the coaxial coupler is exposed to the plasma or to metal vapour. A microwave launcher is a device (not shown) which provides impedance matching between the hollow waveguide 404 and a larger space (e.g. the environment 401). In case a hollow waveguide is used, a microwave window 405 may also be provided. A microwave window 405 serves to allow microwave radiation to pass through, while maintaining continuity of the solid wall of the enclosure 400, which may be required to sustain a pressure difference (e.g. vacuum inside the enclosure 400, atmospheric pressure outside).

Alternatively, the waveguide 404 may be a coaxial waveguide. In this case, a microwave feedthrough may be provided in place of the microwave window 405. The microwave feedthrough may allow microwave radiation to be introduced into the enclosure 400 while maintaining continuity of the solid wall of the enclosure 400.

In either case, the microwave window 405 or microwave feedthrough may be placed outside the environment 401. As such, the microwave window 405 or feedthrough can be prevented from coming into contact with the additional plasma 432 and/or gases within the environment 401. For example, as a result of EUV generation, the environment 401 may contain a concentration of metal vapour, which could condense on the microwave window 405 or feedthrough if it were located inside the environment 401. Therefore, by placing the microwave window 405 or feedthrough outside the environment, such condensation of metal vapour may be avoided or reduced.

In particular, the lithographic apparatus 100 may be configured to prevent the plasma 432 from flowing along a straight line between the surface 402 and the microwave window 405 or feedthrough. For example, a solid wall may be provided to interrupt a straight-line path between the surface 402 and the microwave window 405 or feedthrough. In other words, the lithographic apparatus 100 may be configured to avoid any direct line-of-sight between the surface 402 and the microwave window 405 or feedthrough. For example, the solid wall may be part of the hollow waveguide 404 mentioned above. In particular, the waveguide 404 may have a bend, such as to form an L shape, as shown in FIG. 5. It is to be understood that the waveguide 404 may have more than one bend, and may also have curved portions as may be required by the space constraints within the lithographic apparatus 100.

Furthermore, because the microwave generator 410 is located outside the environment 401, the microwave generator 410 may be replaceable while the lithographic apparatus 100 is operating to manufacture devices. This is because, when the lithographic apparatus 100 is operating to manufacture devices, cleaning of the surface 402 may not be required, and thus the microwave generator 410 is not required to operate. Furthermore, because the microwave generator 410 is located outside the environment 401, it may be possible to remove and/or install the microwave generator 410 without interrupting the process that is taking place within the environment 401 during the manufacture of devices. More particularly, because of the flexibility in the placement of the microwave generator 410, the microwave generator 410 may be placed in a location within the lithographic apparatus 100 which is easily accessible by maintenance personnel even when the lithographic apparatus 100 is operating to manufacture devices.

As some environments 401 in the lithographic apparatus 100 may be under vacuum, if a hollow waveguide 404 is used, a gate valve (not shown) may be provided at some point along the waveguide 404. By closing the gate valve, the vacuum may be maintained while the microwave generator 410 is being replaced. By maintaining the vacuum, any process that is taking place within the environment 401 may continue without interruption. However, preferably the microwave generator is placed outside the vacuum and separated by means of a vacuum window which is arranges such that the microwave passes through it. Such arrangement has the advantage that the microwave generator can be exchanged at any time without affecting the vacuum.

Therefore, if the microwave generator 410 becomes faulty, it may be possible to replace the microwave generator 410 with a new one without interrupting manufacturing operations. This may increase the availability of the lithographic apparatus 100 because the downtime associated with replacing the microwave generator 410 may be reduced or eliminated entirely. By way of comparison, the time it takes to replace a component within an environment within the lithographic apparatus 100 may be one day or more.

Because of the flexibility provided by the present invention, additional plasma 432 may be provided wherever it is required within the lithographic apparatus 100, provided that there is a sufficient base concentration of plasma 431 resulting from EUV generation. This may cover a wide variety of environments 401 within the lithographic apparatus 100.

For example, as shown in FIGS. 3 and 4, the surface 402 may be a surface within an EUV laser-produced plasma (LPP) source vessel 212. For example, as shown in FIG. 4, the surface 402 may comprise the surface of a collector mirror CO within the vessel 212, particularly the optical surface of the collector mirror CO. The surface of the collector mirror CO may be particularly prone to accumulate e.g. tin residues. Therefore, the additional plasma 432 may be usefully generated adjacent the surface of the collector mirror CO so as to ionize and remove the residues. For example, the additional plasma 432 may boost tin etching. As shown, the magnetic source 420 may comprise a magnetic source 420 embedded in the collector mirror CO. More specifically, the magnetic source 420 may be provided behind the optical surface 402 of the collector mirror CO. The magnetic source 420 may be completely encased within the bulk material of the collector mirror CO, which may further lower or eliminate the amount of plasma coming into contact with the magnetic source 420. The magnetic source 420 may generate a magnetic field adjacent the surface of the collector mirror CO so that, together with the microwave radiation 411 provided into the vessel 212, the additional plasma 432 may be generated. As noted above, the magnetic source 420 may comprise a plurality of magnets, such as shown in FIG. 4. Furthermore, multiple portions of the surface 402 of the collector mirror CO may be cleaned. This may be achieved by providing a magnetic source 420 corresponding to each of the portions of the surface 402, so as to generate a magnetic field adjacent each of the portions of the surface 402.

Alternatively or additionally, the surface 402 may comprise an inner wall of the vessel 212 of the EUV LPP source, as shown in FIG. 3. In the example shown in FIG. 3, the magnetic source 420 may be placed outside the enclosure 400 (i.e. the wall of the vessel 212). As noted above, this arrangement may shield the magnetic source 420 from the plasma 432. Furthermore, in order to provide cleaning to the inner wall of the vessel 212, which may be of a generally conical shape, the magnetic source 420 may comprise an array of magnets arranged to follow the shape of the vessel 212. The magnetic fields generated by the magnetic source 420 may be sufficiently strong to penetrate the enclosure 400 and provide the requisite strength of magnetic field adjacent the inner wall 402 in order to generate the additional plasma 432.

As shown in FIGS. 3 and 4, the vessel 212 of the EUV LPP source may comprise an exhaust 403, which may serve to remove gasses and/or contaminants from the environment 401. In this arrangement, the microwave radiation 411 may be provided into the vessel 212 via the exhaust 403. As shown in FIGS. 3 and 4, the exhaust 403 may comprise an opening though which microwave radiation 411 from the microwave generator 410 may enter the exhaust 403, and ultimately into the vessel 212. As noted above, it may be desirable to avoid a direct line-of-sight between the surface 402 and the microwave window 405 or feedthrough. By placing the point of introduction of microwave radiation along the exhaust 403, and by placing the microwave window 405 or feedthrough some distance away from the exhaust 403, any direct line-of-sight between the surface 402 and the microwave window 405 or feedthrough may be avoided. A microwave launcher (not shown) may be provided to introduce the microwave radiation into the exhaust 403. The microwave launcher may serve to provide impedance matching for the microwave radiation entering into the exhaust 403

The microwave generator 410 may be connected to the exhaust 403 via a waveguide. As noted above, the waveguide may comprise bends and/or curved portions as necessary. Furthermore, as shown in FIGS. 3 and 4, the vessel 212 may comprise a narrow opening at the virtual source point IF. In order to prevent leakage of the microwave radiation 411, the IF opening may be sufficiently small compared with the wavelength of the microwave radiation 411.

Alternatively or additionally, the surface 402 may comprise the optical surface of a MEMS mirror device 22, 24, as shown in FIG. 5. As shown, a MEMS mirror device 22, 24 may comprise an array of MEMS mirrors, each of which may be actuated by a control and sensing mechanism 251. Furthermore, wiring 252 may be present behind the optical surface 402 and the control and sensing mechanism 251, in a control base of the MEMS mirror device 22, 24. Because components such as the control and sensing mechanism 251 and wiring 252 may reflect or absorb electromagnetic waves, microwave radiation 411 may be advantageously provided from the mirror side of the MEMS mirror device 22, 24 as shown. As shown in FIG. 5, the magnetic source 420 may still be provided on the side opposite the optical surface 402 of the MEMS mirror device 22, 24. As noted above, the magnetic field from the magnetic source 420 may penetrate through the sensing mechanism 251, wiring 252 and the control base, etc., to the optical surface 402 of the MEMS mirror device 22, 24. With this arrangement, it may be possible to generate the additional plasma 432 adjacent to the optical surface 402 of the MEMS mirror device 22, 24 without obstructing the optical paths to and from the MEMS mirror device 22, 24.

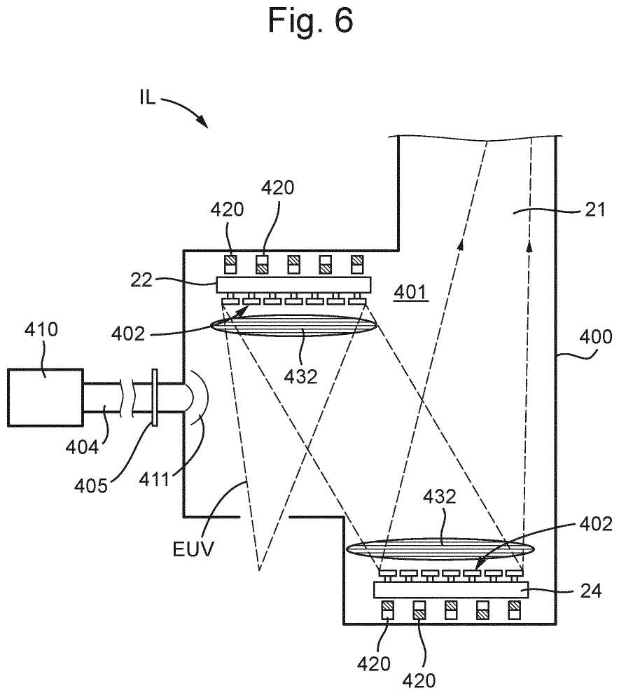

As shown in FIG. 6, the MEMS mirror device 22, 24 may be part of an illuminator IL of the lithograph apparatus 100. As shown, two MEMS mirror devices 22, 24 may be provided in the illuminator IL. The MEMS mirror devices may include the facetted field mirror device 22 and the facetted pupil mirror device 24 mentioned above. As noted above, surfaces in the illuminator IL may be particularly prone to accumulate water molecules after pump-down of the lithography apparatus 100. Because the optical surfaces 402 of the MEMS mirror devices 22, 24 are exposed to EUV radiation, any water molecule present on the optical surface 402 may be broken down by the EUV radiation into harmful particles as explained above. Therefore, it may be beneficial to remove these water molecules using the additional plasma 432. A water vapour pressure below 107 mbar, preferably about 108 mbar, may be required.

Because water molecules can be effectively released from the optical surface 402 of the MEMS mirror device 22, 24, pump-down time can be reduced. For example, a ten-fold reduction in pump-down time may be achievable. A shorter pump-down time may be desirable because it may reduce the damage to the cap layer or underlayers of the MEMS mirror device 22, 24 due to deep oxidation during start-up. This is particularly so because MEMS illuminators may be particularly affected by deep oxidation.

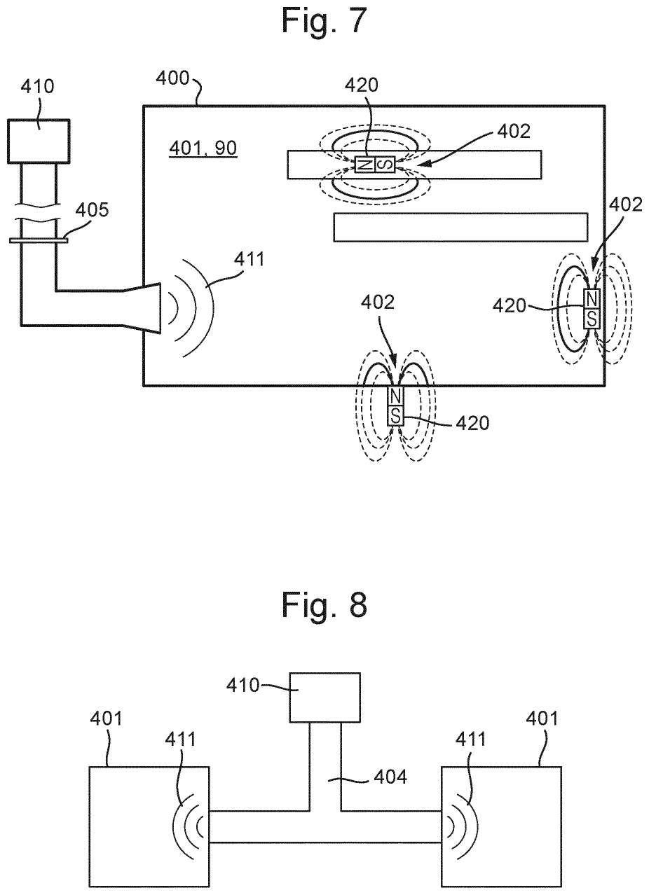

As noted above, the additional plasma 432 may be provided according to the present invention in various environments 401 within the lithographic apparatus 100, particularly where there is a sufficient concentration of plasma 431 resulting from EUV generation. For example, as shown in FIG. 7, additional plasma 432 may additionally or alternatively be provided to various surfaces 402 within the patterning device environment 90. As yet another example not shown in the figures, the surface 402 may comprise a window for metrology. In particular, the magnetic source 420 may be embedded within the window, blocking only a small part of the cross-section of the window. With this arrangement, the material for the window may be chosen in favour of chemical compatibility (e.g. with hydrogen plasma) without affecting the cleaning functionality of the present invention.

As noted above, multiple surfaces 402 within an environment 401, 90 may be exposed to the additional plasma 432 generated using the microwave radiation 411 from the microwave generator 410. Additionally or alternatively, the same microwave generator 410 may provide microwave radiation 411 into several environments 401, 90. Each of these environments 401, 90 may in turn contain one or more surface 402 requiring exposure to the additional plasma 432. As shown in FIG. 8, as an example, the microwave generator 410 may provide microwave radiation 411 into two environments 401. The microwave radiation 411 may be provided via a wave guide 404 which connects to the microwave generator 410 at one end, and branches out to the two environments 401 as shown. Furthermore, the wavelength of the microwave radiation 411 may be varied according to each environment 401 so that the conditions for electron cyclotron resonance is met at the location where the additional plasma 432 is required.

In general, the microwave generator 410 may be activated constantly, for example if the generation of plasma 432 is required continuously. Similarly, the magnetic source 420 may also be activated constantly. However, in some implementations, the microwave generator 410 may be activated selectively (i.e. when required). Similarly, the magnetic source 420 may be activated selectively. For example, the generation of additional plasma 432 may not be required when few contaminants capable of forming residues on the surface 402 are being generated. More generally, in some implementations, prolonged exposure to the additional plasma 432 can damage the surface 402. Therefore, in some implementations, it may be desirable to activate the generation of additional plasma 432 only when cleaning of the surface 402 is desired.

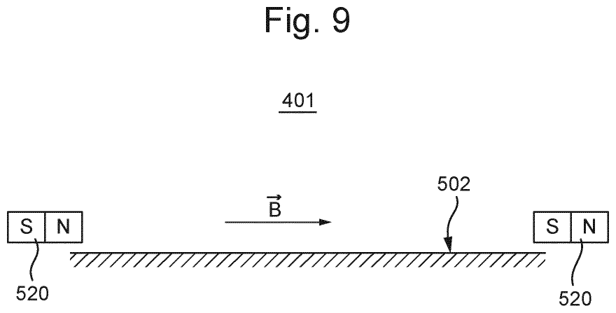

With reference to FIG. 9, to further protect a surface 502 from exposure to plasma (e.g. the base concentration of plasma 431 resulting from EUV radiation), a second magnetic source 520 may be provided. The second magnetic source 520 may be configured to generate a magnetic field [symbol] which is adjacent and parallel to the second surface 502. The second surface 502 may be encompassed by the environment 401. As found by the present inventors, the magnetic field [symbol] can invert the plasma potential (i.e. a negative potential difference between the plasma and the surface 502). In one experimental setup, it was found that an inversion of the plasma potential can be achieved by applying a magnetic field [symbol] of about 20-30 Gauss (2-3 mT). This negative potential difference may repel ions away from the surface 502, thereby protecting the surface 502 from damage.

Certain surfaces within the lithographic apparatus 100 may particularly benefit from such protection. For example, multilayer mirrors may be used to transport the light through the lithographic apparatus 100. These mirrors may be exposed to a hydrogen plasma (ionized gas) resulting from EUV generation. A positive potential difference (plasma potential) may build up between the plasma and the mirrors, which may accelerate ions from the plasma towards to mirrors with energies up to 25 eV. These high energy ions are mainly generated during and just after the EUV pulse; the low energy ions are generated later in time (>1 μs). Therefore, although these ions ensure can help the optics stay clean, prolonged exposure may cause damage (mainly due to the high energy ions).

In the foregoing disclosure, in the general case, the first surface 402 and the second surface 502 may be different surfaces within the environment 401. In some cases, the first and second surfaces 402, 502 may overlap, or may be the same surface. The first and second surfaces 402, 502 may be coincidental.

The second magnetic source 520 may be selectively activated (e.g. when protection of the surface 502 is required). The second magnetic source 520 may be an electromagnet, which may allow selective activation.

As noted above, the first magnetic source 420 may also be selectively activated, so that additional plasma 432 can be generated when needed. The second magnetic source 520 may achieve the opposite effect, namely to repel plasma ions, for the purpose of protecting the surface 502. The lithographic apparatus 100 may selectively activate either the first magnetic source 420 or the second magnetic source 520 at any given time. The lithographic apparatus 100 may be configured not to simultaneously activate both the first and second magnetic sources 420, 520. In particular, by selectively activating/deactivating the first and second magnetic sources 420, 520, it is possible to dose the surface 402/502 with an amount of plasma adequate for cleaning while limiting damage to the surface 402/502. The first and second magnetic sources 420, 520 may also be controlled in synchrony with the EUV pulses. For example, the second magnetic source 520 may be activated when the energy is highest (during and shortly after the EUV pulse), which causes the most damage.

As noted above, the additional plasma 432 may be generated adjacent the surface 402. This may be useful for cleaning the surface 402. In other words, the additional plasma 432 can be said to be generated in situ (i.e. generated where it is used). However, it is also possible to extract the additional plasma 432 from the environment 401 for further use.

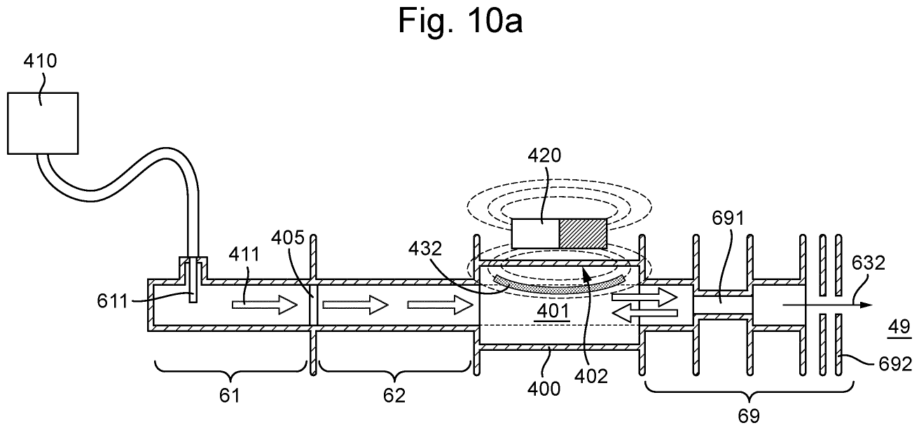

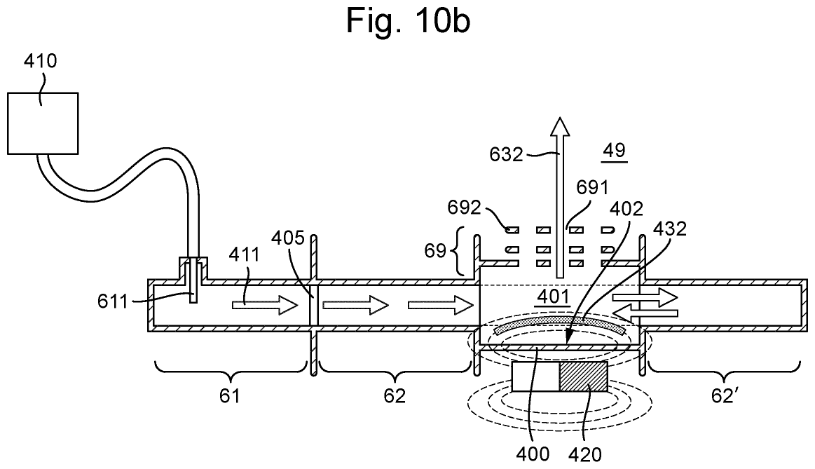

Referring to FIG. 10a, a plasma extractor 69 may be provided to extract at least a portion of the additional plasma 432 from within the environment 401 to outside the environment 49. As shown, the microwave radiation 411 may enter the environment 401 and propagate principally in a longitudinal direction of the enclosure 400. The plasma extractor 69 may be provided opposite the entrance point of the microwave radiation 411, and may be in alignment with the longitudinal direction. As shown, the extracted plasma 632 may flow substantially in the longitudinal direction.

Additionally or alternatively, as shown in FIG. 10b, the plasma extractor 69 may be not in alignment with the direction of propagation of the microwave radiation 411. For example, the plasma extractor 69 may be provided to one side of the enclosure 400, so that the flow direction of the extracted plasma 632 is not in the longitudinal direction. For example, the plasma extractor 69 may be positioned such that the extracted plasma 632 flows in a direction substantially orthogonal to the direction of propagation of the microwave radiation 411.

As shown in FIGS. 10a and 10b, the plasma extractor 69 may comprise an aperture 691. The aperture 691 may allow the additional plasma 432 to be extracted therethrough. At the same time, the aperture 691 may cause an impedance change which prevents at least a portion of the microwave radiation 411 within the environment 401 from exiting through the aperture 691. Instead, due to the impedance change, the microwave radiation 411 may be reflected back into the environment 401. This may reduce the microwave power emission to outside the environment 49. This may also make more efficient use of the microwave radiation 411 provided into the enclosure 400.

The magnetic source 420 may provide a static magnetic field within the enclosure 400, which may promote resonant absorption of microwave power inside the enclosure 400. The magnetic source 420 may comprise a symmetric or asymmetric arrangement of magnets, such as simple dipoles. The magnetic source 420 may encompass the enclosure 400. The magnetic source 420 may be permanent magnets and/or electromagnets.

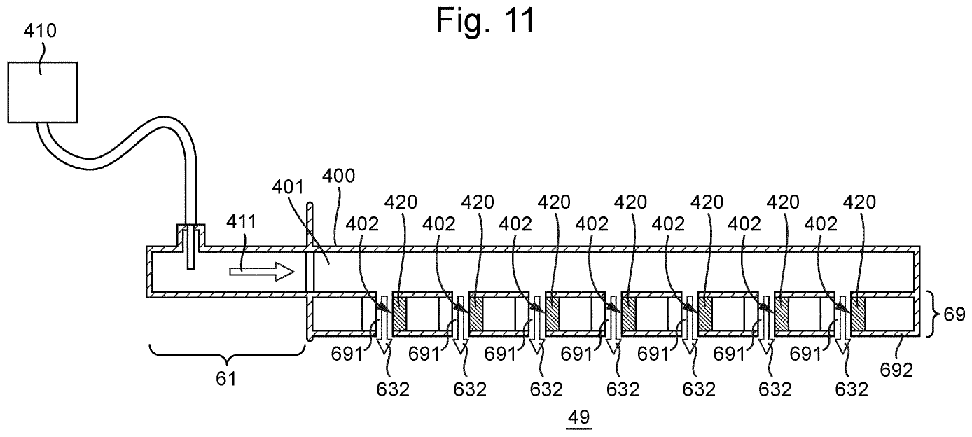

Referring to FIG. 11, the plasma extractor 69 may comprise more than one aperture 691. A plurality of apertures 691 may be provided. As before, each aperture 691 may allow the plasma to be extracted therethrough. Each aperture 691 may induce an impedance change which prevents at least a portion of the microwave radiation 411 within the environment 401 from exiting through the aperture 691. This may allow the additional plasma 432 to be extracted at a greater rate, while preventing the emission of microwave radiation 411 to outside the environment 49.

In the arrangement shown in FIG. 11, the enclosure 400 is elongate, and the plurality of apertures 691 are arranged along the longitudinal axis of the enclosure 400. However, it should be understood that other arrangements of the plurality of apertures 691 may be employed as required.

The additional plasma 432 may be generated by a single magnetic source 420 as shown in FIGS. 10a and 10b. Additionally or alternatively, as shown in FIG. 11, each of the plurality of apertures 691 may be associated with a separate magnetic source 420 for plasma generation. In particular, as shown, each magnetic source 420 may be integrated with the respective aperture 691. That is, each aperture 691 may be formed in the respective magnetic source 420. In this arrangement, the plasma 632 may be extracted as soon as it is generated. Furthermore, the plurality of magnetic sources 420 may be operated in different modes (e.g. plasma, electron- and/or ion beam). For example, plasma generation next to particle beams can be used for compensating space charge of extracted charged particle beams.

To further enhance the extraction of plasma, as shown in FIGS. 10a, 10b, and 11, the plasma extractor 69 may further comprise extraction electrodes 692. A voltage bias may be generated using the extraction electrodes 692, which may promote the extraction of the plasma 632. In embodiments, the extraction electrodes 692 may be configured to extract the plasma 632 as an ion beam. A power supply may be connected to the extraction electrodes 692 to maintain the voltage bias. Alternatively, the bias voltage of the extraction electrodes 692 may be maintained with diodes, so that no power supply or cable would be needed. Cables to power supplies cannot always be easily connected to narrow parts that need to be biased. Surfaces exposed to plasma without connection to ground or any other reference potential may ‘float’ at an electric potential in an uncontrolled manner. By use of for example Zener diodes, they can be used to bias surfaces in lithographic apparatuses or other tools where there are spaces that cannot easily be reached by cables. Zener diodes can also be used to bias object or surfaces exposed to plasma or charged particle beams (electron beams or ion beams) in an controlled manner avoiding the use of a power supply and cables providing the bias voltage. In an embodiment, a pellicle 80 can be biased relative to the reticle frontside by electrically insulating the pellicle 80 from the reticle frontside and establishing contact to the reticle frontside via the Zener diode. The Zener diode can also be a load bearing part of the pellicle support structure (i.e. a pellicle frame that connect a pellicle film to the reticle frontside). Also, electrodes of plasma generators in EUV scanners or plasma generators themselves may be biased using Zener diodes.

In some arrangements, several extraction electrodes 692 may be provided to enable space charge compensation and/or beam focusing. Furthermore, the use of several extraction electrodes 692 may be beneficial for reducing (potentially unavoidable) erosion of the electrodes. Additionally, the extraction electrodes 692 may be asymmetric, which can be used to steer the beam or compensate for effects due to (asymmetric) magnetic stray field. Furthermore, fins may be provided between the extraction electrodes 692. These fins may be used to block crossed-field promoted discharges. Crossed-field drift can also be used to extract charged particle beams and/or avoid or prevent erosion of the extraction electrodes 692.

In embodiments, the extraction electrodes 692 may be omitted. That is, the plasma (or electrons) may be extracted without the need for a bias voltage, for example by using a waveguide with holes. This may reduce the size of the plasma extractor 69.

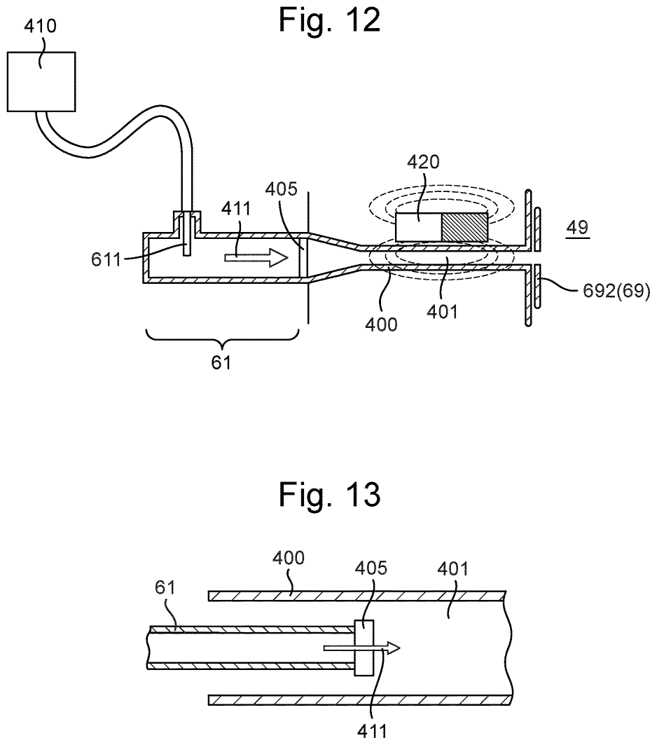

Referring to FIG. 12, the enclosure 400 may be elongate and may have a transverse cross-sectional area smaller than required for propagation of the microwave radiation 411 as electromagnetic waves. Instead, microwave energy may penetrate into the enclosure 400 as an evanescent wave. The evanescent wave, together with the magnetic field provided by the magnetic source 420, may enable the generation of the additional plasma 432. The use of an enclosure 400 with a small cross-section may reduce the size of the enclosure 400.

The enclosure 400 may be made of a material with low sputter yield. The enclosure 400 may be covered with a dielectric coating or liner (e.g. low sputter yield material such as Yttria). Plasma surface interaction at plasma strike-points may be managed by various additional features, such as thicker material, low sputter material, small wells or ‘beam dumps’ or openings (to move the strike point outside the enclosure 400, which provides geometric shielding for material emission from strike point region).

As shown in FIGS. 11 and 12, a microwave coupler 61, an antenna 611 by which the microwave radiation is provided, and a microwave window 405 may be present. The antenna 611 may be provided at a first end of the microwave coupler 61. A second end of the microwave coupler 61 may be coupled to the enclosure 400 at a junction. The microwave window 405 may be located at the junction, and may allow the microwave radiation 411 to pass through while fluidly isolating the microwave coupler 61 from the environment 401 encompassed by the enclosure 400. This may enable the environment 401 to be maintained at a pressure different from within the microwave coupler 61. Furthermore, the microwave window 405 may serve to shield the antenna 611 from the additional plasma 432 generated within the enclosure 400.

Referring to FIG. 13, the second end of the microwave coupler 61 may extend into the enclosure 400. Furthermore, the second end of the microwave coupler 61 may be suspended within the enclosure 400, so as to allow relative movement between the second end of the microwave coupler and the enclosure. For example, the microwave coupler 61 may be suspended within the enclosure 400 without direct mechanical contact. The enclosure 400 surrounding the microwave coupler 61 may be little more than big enough to accommodate the microwave coupler 61, so that the impedance change going from the microwave coupler 61 into the enclosure 400 may be kept small. This may reduce the amount of reflected microwave radiation 411.

Also shown in FIGS. 10a and 10b is an optional waveguide 62, which may be part of the enclosure 400. The waveguide 62 may transmit the microwave radiation 411 from the microwave coupler 61 to a location within the enclosure 400 where the magnetic field provided by the magnetic source 420 is present. As noted above, a microwave window 405 may be provided. The waveguide 62 may be shaped (not shown) so that the microwave window 405 is not within a line of sight to the additional plasma 432. Furthermore, the internal volume of the waveguide 62 may have a variety of cross-sectional shape, for example circular, elliptical, square, rectangular, C-shaped, or H-shaped.

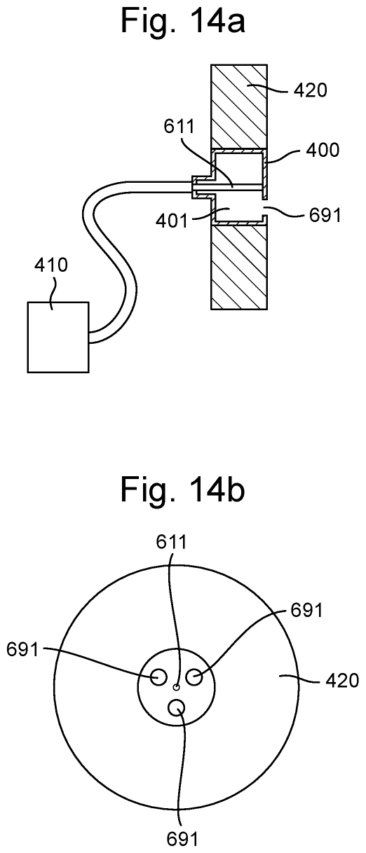

As noted above, the magnetic source 420 may have a variety of shapes or arrangements. As shown in FIGS. 14a and 14b, the magnetic source 420 may comprise a circular Halbach array surrounding the enclosure 400. As shown, an antenna 611 may be provided to introduce the microwave radiation 411 into the enclosure 400. The antenna 611 may extend into the enclosure 400 along a longitudinal axis. The antenna 611 may be co-extensive with the enclosure 400 in the longitudinal direction. The Halbach array may be substantially concentric with the antenna 611 and may have an overlapping longitudinal extent with the antenna 611. For example, the Halbach array may be co-extensive with the antenna 611 in the longitudinal direction. In other words, the enclosure 400 and the antenna 611 may together form a coaxial plasma chamber. Different configurations of the circular Halbach array may be used. For example, the circular Halbach array may be a quadrupole, a hexapole, or an octupole. With this arrangement, microwaves at all frequencies can propagate in the enclosure 400 irrespective of its size. This may enable the enclosure 400 to be miniaturized.

As shown, one or more aperture 691 may be provided to extract the plasma from within the enclosure 400. The one or more aperture 691 may be offset from the longitudinal axis of the antenna 611. Off-axis apertures 691 may prevent erosion of the antenna 611.

Where the foregoing disclosure refers to “plasma”, it should be understood that electrons (which are also charged particles) may be generated instead. Accordingly, where the foregoing disclosure refers to extracting the plasma as a “ion beam”, it should be understood that, in embodiments configured to generate electrons, an electron beam would result.

In one embodiment, the above mentioned components and methods, including the embodiments illustrated by FIGS. 6, 8, 9, 10, 11, 12, 13, and 14, are implemented in other apparatus than lithographic apparatus, optionally in a metrology apparatus, and optionally in an inspection apparatus. In one embodiment, these embodiments are implemented in a SXR apparatus. A SXR apparatus is a apparatus which comprises a source which emits SXR and/or EUV radiation. Optionally these embodiments are implemented in a SXR metrology apparatus, and/or a SXR inspection apparatus. One example of the SXR apparatus is as described in WO2023165783A1, which is incorporated herein by reference in the entirety. Ions may be created in flushing environment around SXR optical elements, e.g. the illumination system/optics and/or the filtering device as in WO2023165783A1, and, depending on the choice of flushing gas, they may harm coatings of the SXR optical element. In one embodiment, the surface 502 in FIG. 9 is a surface of the illumination system/optics and/or a surface of the filtering devices within a metrology/inspection apparatus. In one embodiment, the filtering device comprises a Zirconium film. In one embodiment, the filtering device is a pellicle. In one embodiment, the surface 502 in FIG. 9 is any of the surfaces as in WO2023165783A1 that is exposed to plasma. In one embodiment, the illumination optics is a reflective mirror, optionally a reflective curved mirror, and optionally a toroidal mirror. Optionally the reflective mirror comprises a diffractive element, e.g. a grating, in its reflective surface. Optionally the reflective mirror is a toroidal mirror with a grating. The ions may be induced by SXR radiation, and due to existence of the ions, some gases have to be excluded from flushing gasses of the apparatus. The embodiments mention in the above paragraphs may enable to use the gasses. A magnetic field may be applied to surface of the SXR optics, optionally parallel to the surface, to deflect the electrons and hence change the plasma potential even to such an extent that the potential reverses, i.e. obtain the inversion of the plasma potential. The negative potential difference between the plasma and the surface may be obtained because positive ions have charged the surface. Besides apparatus with high harmonic generation (HHG) source, the above embodiments also applicable to apparatus with other light sources, e.g. laser produced plasma (LPP) source, discharge produced plasma (DPP) source, and free electron laser (FEL) source. The method to adapt the magnetic field strength to a specific situation may enable to also find a beneficial field strength for a specific optics, where the specific optics are cleaned but not damaged. In another embodiment, the enclosure mentioned in the above embodiments is replaced by a vessel.

Although specific reference may be made in this text to the use of a lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc.

Where the context allows, embodiments of the invention may be implemented in hardware, firmware, software, or any combination thereof. Embodiments of the invention may also be implemented by instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic storage media; optical storage media; flash memory devices; electrical, optical, acoustical or other forms of propagated signals (e.g. carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc. and in doing that may cause actuators or other devices to interact with the physical world.

Although specific reference may be made in this text to embodiments of the invention in the context of a lithographic apparatus, embodiments of the invention may be used in other apparatus. Embodiments of the invention may form part of a mask inspection apparatus, a metrology apparatus, or any apparatus that measures or processes an object such as a wafer (or other substrate) or mask (or other patterning device). These apparatus may be generally referred to as lithographic tools.

In one embodiment, the metrology apparatus is configured to measure a parameter of interest of a process that is not a lithographic process. For example, the metrology apparatus is configured to measure a parameter of an etching process.

Although specific reference may have been made above to the use of embodiments of the invention in the context of optical lithography, it will be appreciated that the invention, where the context allows, is not limited to optical lithography.

Aspects of the invention are described in the following numbered clauses.
1. A lithographic apparatus (100) comprising:
an enclosure (400) defining an environment (401), wherein the environment encompasses a surface (402), wherein the enclosure is configured to contain plasma;
a microwave generator (410) configured to provide microwave radiation (411) into the enclosure;
a magnetic source (420) configured to generate a magnetic field adjacent the surface which, together with the microwave radiation, generates plasma (432) by electron cyclotron resonance, thereby increasing the concentration of plasma adjacent the surface.
2. The lithographic apparatus of clause 1, wherein:
the microwave generator is located outside the environment; and
the enclosure is configured to contain a base concentration of plasma (431) resulting from EUV radiation.
3. The lithographic apparatus of clause 1 or clause 2, wherein the enclosure is configured to contain hydrogen gas.
4. The lithographic apparatus of any one of the preceding clauses, wherein the plasma comprises hydrogen plasma.
5. The lithographic apparatus of any one of the preceding clauses, wherein the magnetic source comprises a permanent magnet and/or an electromagnet.
6. The lithographic apparatus of any one of the preceding clauses, wherein the magnetic source comprises a plurality of permanent magnets and/or a plurality of electromagnets.
7. The lithographic apparatus of any one of the preceding clauses, wherein the magnetic source is shielded from the plasma.
8. The lithographic apparatus of any one of the preceding clauses, wherein the magnetic source is located outside the enclosure.
9. The lithographic apparatus of any one of the preceding clauses, further comprising a waveguide (404) configured to guide the microwave radiation from the microwave generator into the enclosure.
10. The lithographic apparatus of any one of the preceding clauses, configured to prevent the plasma from flowing along a straight line between the surface and a microwave window (405) through which the microwave radiation from the microwave generator travels into the enclosure.
11. The lithographic apparatus of any one of the preceding clauses, wherein the microwave generator is replaceable while the lithographic apparatus is operating to manufacture devices.
12. The lithographic apparatus of any one of the preceding clauses, wherein the surface comprises a surface within an EUV laser-produced plasma source vessel (212).
13. The lithographic apparatus of clause 12, wherein the surface comprises the surface of a collector mirror (CO) within the vessel.
14. The lithographic apparatus of clause 13, wherein the magnetic source comprises a magnetic source embedded in the collector mirror.
15. The lithographic apparatus of any one of clauses 12 to 14, wherein the surface comprises an inner wall of the vessel.
16. The lithographic apparatus of any one of clauses 12 to 15, wherein the vessel comprises an exhaust (403), and the microwave radiation is provided into the vessel via the exhaust.
17. The lithographic apparatus of any one of the preceding clauses, wherein the surface comprises a window for metrology.
18. The lithographic apparatus of clause 17, wherein the magnetic source comprises a magnetic source embedded in the window.
19. The lithographic apparatus of any one of the preceding clauses, wherein the surface comprises the optical surface of a MEMS mirror device (22, 24).
20. The lithographic apparatus of clause 19, wherein the MEMS mirror device is part of an illuminator (IL) of the lithographic apparatus.
21. The lithographic apparatus of any one of the preceding clauses, comprising a plurality of said environments, wherein the microwave generator is configured to provide microwave radiation into each of the plurality of environments.
22. The lithographic apparatus of any one of the preceding clauses, further configured to selectively activate the microwave generator.
23. The lithographic apparatus of any one of the preceding clauses, further configured to selectively activate the magnetic source.
24. The lithographic apparatus of any one of the preceding clauses, further comprising a second magnetic source (520) configured to generate a magnetic field (B) adjacent and parallel to a second surface (502) encompassed by the environment.
25. The lithographic apparatus of clause 24, wherein the second magnetic source comprises an electromagnet.
26. The lithographic apparatus of clause 24 or clause 25, wherein the first and second surfaces are coincidental.
27. The lithographic apparatus of any one of clauses 24 to 26, further configured to selectively activate the second magnetic source.
28. The lithographic apparatus of any one of clauses 24 to 26, further configured to selectively activate either the first magnetic source or the second magnetic source at a time, and not both simultaneously.
29. The lithographic apparatus of any one of the preceding clauses, further comprising a plasma extractor (69) configured to extract at least a portion of the plasma from within the environment to outside the environment (49).
30. The lithographic apparatus of clause 29, wherein the plasma extractor comprises an aperture (691) configured to allow the plasma to be extracted therethrough, and to cause an impedance change which prevents at least a portion of the microwave radiation within the environment from exiting through the aperture.
31. The lithographic apparatus of clause 29, wherein the plasma extractor comprises a plurality of apertures (691) each configured to allow the plasma to be extracted therethrough, and to induce an impedance change which prevents at least a portion of the microwave radiation within the environment from exiting through the aperture.
32. The lithographic apparatus of clause 31, wherein the enclosure is elongate, and the plurality of apertures are arranged along the longitudinal axis of the enclosure.
33. The lithographic apparatus of clause 31 or clause 32, wherein each of the plurality of apertures is associated with a separate magnetic source for plasma generation.
34. The lithographic apparatus of any one of clauses 24 to 33, wherein the plasma extractor further comprises extraction electrodes (692).
35. The lithographic apparatus of any one of clauses 24 to 34, wherein the enclosure is elongate and has a transverse cross-sectional area smaller than required for propagation of the microwave radiation as electromagnetic waves, so that microwave energy penetrates into the enclosure as an evanescent wave.
36. The lithographic apparatus of any one of clauses 30 to 35, further comprising a microwave coupler (61), an antenna (611) by which the microwave radiation is provided, and a microwave window (405), wherein:
the antenna is provided at a first end of the microwave coupler;
a second end of the microwave coupler is coupled to the enclosure at a junction; and
the microwave window is located at the junction, and is configured to allow the microwave radiation to pass through while fluidly isolating the microwave coupler from the environment encompassed by the enclosure.
37. The lithographic apparatus of clause 36, wherein the second end of the microwave coupler extends into the enclosure.
38. The lithographic apparatus of clause 37, wherein the second end of the microwave coupler is suspended within the enclosure, so as to allow relative movement between the second end of the microwave coupler and the enclosure.
39. The lithographic apparatus of any one of clauses 34 to 38, wherein the extraction electrodes have an asymmetric arrangement.
40. The lithographic apparatus of any one of clauses 24 to 39, wherein the second magnetic source has an asymmetric arrangement.
41. The lithographic apparatus of clause 30 or clause 31, further comprising an antenna (611) by which the microwave radiation is provided into the enclosure; wherein:
the antenna extends into the enclosure along a longitudinal axis; and
the magnetic source comprises a circular Halbach array surrounding the enclosure, the Halbach array being substantially concentric with the antenna and having an overlapping longitudinal extent with the antenna.
42. The lithographic apparatus of clause 41, wherein the one or more aperture is offset from the longitudinal axis of the antenna.
43. The lithographic apparatus of clause 41 or clause 42, wherein the circular Halbach array is a quadrupole, a hexapole, or an octupole.
44. A method comprising:
providing, by a microwave generator (410), microwave radiation (411) into an enclosure (400), wherein the enclosure defines an environment (401) in a lithographic apparatus (100), and the environment encompasses a surface (402); and
generating, by a magnetic source (420), a magnetic field adjacent the surface which, together with the microwave radiation, generates plasma (432) by electron cyclotron resonance, thereby increasing the concentration of plasma adjacent the surface.
45. The method of clause 44, wherein:
the microwave generator is located outside the environment; and
the enclosure contains a base concentration of plasma (431) resulting from EUV radiation.
46. The method of clause 44, wherein the enclosure contains hydrogen gas.
47. The method of any one of clauses 44 to 46, wherein the plasma comprises hydrogen plasma.
48. The method of any one of clauses 44 to 47, wherein the magnetic source comprises a permanent magnet and/or an electromagnet.
49. The method of any one of clauses 44 to 48, wherein the magnetic source comprises a plurality of permanent magnets and/or a plurality of electromagnets.
50. The method of any one of clauses 44 to 49, wherein the magnetic source is shielded from the plasma.
51. The method of any one of clauses 44 to 50, wherein the magnetic source is located outside the enclosure.
52. The method of any one of clauses 44 to 51, wherein the providing the microwave radiation comprises guiding the microwave radiation from the microwave generator into the enclosure via a waveguide (404).
53. The method of any one of clauses 44 to 52, wherein the plasma is prevented from flowing along a straight line between the surface and a microwave window (405) through which the microwave radiation from the microwave generator travels into the enclosure.
54. The method of any one of clauses 44 to 53, wherein the surface comprises a surface within an EUV laser-produced plasma source vessel (212).
55. The method of clause 54, wherein the surface comprises the surface of a collector mirror (CO) within the vessel.
56. The method of clause 55, wherein the magnetic source comprises a magnetic source embedded in the collector mirror.
57. The method of any one of clauses 54 to 56, wherein the surface comprises an inner wall of the vessel.
58. The method of any one of clauses 54 to 57, wherein the vessel comprises an exhaust (403), and the microwave radiation is provided into the vessel via the exhaust.
59. The method of any one of clauses 44 to 58, wherein the surface comprises a window for metrology.
60. The method of clause 59, wherein the magnetic source comprises a magnetic source embedded in the window.
61. The method of any one of clauses 44 to 60, wherein the surface comprises the optical surface of a MEMS mirror device (22, 24).
62. The method of clause 61, wherein the MEMS mirror device is part of an illuminator (IL) of the lithographic apparatus.
63. The method of any one of clauses 44 to 62, further comprising using the microwave generator to provide microwave radiation into a plurality of said environments.
64. The method of any one of clauses 44 to 63, further comprising selectively activating the microwave generator.
65. The method of any one of clauses 44 to 64, further comprising selectively activating the magnetic source.
66. The method of any one of clauses 44 to 65, further comprising generating, by a second magnetic source, a magnetic field adjacent and parallel to a second surface encompassed by the environment.
67. The method of clause 66, wherein the second magnetic source comprises an electromagnet.
68. The method of clause 66 or clause 67, wherein the first and second surfaces are coincidental.
69. The method of any one of clauses 66 to 68, further comprising selectively activating the second magnetic source.
70. The method of any one of clauses 66 to 69, further configured to selectively activate either the first magnetic source or the second magnetic source at a time, and not both simultaneously.
71. The method of any one of clauses 66 to 69, further comprising extracting, using a plasma extractor, at least a portion of the plasma from within the environment to outside the environment.
72. The method of clause 71, wherein the plasma extractor comprises an aperture which allows the plasma to be extracted therethrough, and which induces an impedance change which prevents at least a portion of the microwave radiation within the environment from exiting through the aperture.
73. The method of clause 71, wherein the plasma extractor comprises a plurality of apertures, wherein each of the apertures allows the plasma to be extracted therethrough, and induces an impedance change which prevents at least a portion of the microwave radiation within the environment from exiting through the aperture.
74. The method of clause 73, wherein the enclosure is elongate, and the plurality of apertures are arranged along the longitudinal axis of the enclosure.
75. The method of clause 73 or clause 74, wherein each of the plurality of apertures is associated with a separate magnetic source for plasma generation.
76. The method of any one of clauses 66 to 75, wherein the plasma extractor further comprises extraction electrodes.
77. The method of any one of clauses 66 to 76, wherein the enclosure is elongate and has a transverse cross-sectional area smaller than required for propagation of the microwave radiation as electromagnetic waves, so that microwave energy penetrates into the enclosure as an evanescent wave.
78. The method of any one of clauses 72 to 77, further comprising providing the microwave radiation via an antenna, through a microwave window and into the enclosure; wherein:
the antenna is provided at a first end of the microwave coupler;
a second end of the microwave coupler is coupled to the enclosure at a junction; and
the microwave window is located at the junction, and allows the microwave radiation to pass through while fluidly isolating the microwave coupler from the environment encompassed by the enclosure.
79. The method of clause 78, wherein the second end of the microwave coupler extends into the enclosure.
80. The method of clause 79, wherein the second end of the microwave coupler is suspended within the enclosure, so as to allow relative movement between the second end of the microwave coupler and the enclosure.
81. The lithographic apparatus of any one of clauses 76 to 80, wherein the extraction electrodes have an asymmetric arrangement.
82. The lithographic apparatus of any one of clauses 66 to 81, wherein the second magnetic source has an asymmetric arrangement.
83. The method of clause 72 or clause 73, further comprising providing, via an antenna, the microwave radiation into the enclosure; wherein:
the antenna extends into the enclosure along a longitudinal axis; and
the magnetic source comprises a circular Halbach array surrounding the enclosure, the Halbach array being substantially concentric with the antenna and having an overlapping longitudinal extent with the antenna.
84. The method of clause 83, wherein the one or more aperture is offset from the longitudinal axis of the antenna.
85. The method of clause 83 or clause 84, wherein the circular Halbach array is a quadrupole, a hexapole, or an octupole.
86. A method of manufacturing devices using the method of any one of clauses 44 to 85.
87. The method of clause 86, further comprising replacing the microwave generator while the lithographic apparatus is operating to manufacture devices.
88. A metrology or inspection apparatus comprising:
   a source emitting a SXR and/or EUV radiation,
   a vessel or enclosure defining an environment, wherein the environment encompasses a surface, wherein the vessel or enclosure is configured to contain plasma resulting from the SXR and/or EUV radiation; and
   a first magnetic source configured to generate a first magnetic field adjacent the surface.
89. The metrology or inspection apparatus of clause 88, wherein the first magnetic source comprises a permanent magnet and/or an electromagnet.
90. The metrology or inspection apparatus of clause 88 or 89, wherein the first magnetic source comprises a plurality of permanent magnets and/or a plurality of electromagnets.
91. The metrology or inspection apparatus of any one of clauses 88 to 90, wherein the first magnetic source is shielded from the plasma.
92. The metrology or inspection apparatus of any one of clauses 88 to 91, wherein the first magnetic source is located outside the vessel or enclosure.
93. The metrology or inspection apparatus of any one of clauses 88 to 92, further configured to selectively activate the first magnetic source.
94. The metrology or inspection apparatus of any one of clauses 88 to 93, wherein the first magnetic source configured to generate the first magnetic field adjacent and parallel to the surface.
95. The metrology or inspection apparatus of any one of clauses 88 to 94, further comprising a second magnetic source configured to generate a second magnetic field adjacent to a second surface encompassed by the environment.
96. The metrology or inspection apparatus of any one of clauses 88 to 95, further comprising a plasma extractor configured to extract at least a portion of the plasma from within the environment to outside the environment.
97. The metrology or inspection apparatus of clause 95, wherein the first and/or the second magnetic source has an asymmetric arrangement.
98. The metrology or inspection apparatus of any one of clauses 88 to 97, wherein the source is a high harmonic generation (HHG) source.
99. The metrology or inspection apparatus of any one of clauses 88 to 97, wherein the source is a laser produced plasma (LPP) source.
100. The metrology or inspection apparatus of any one of clauses 88 to 99, wherein the surface is a reflective surface of a reflective mirror.
101. The metrology or inspection apparatus of clause 100, wherein the reflective mirror is a reflective curved mirror.
102. The metrology or inspection apparatus of clause 101, wherein the reflective mirror is a toroidal mirror.
103. The metrology or inspection apparatus of any one of clauses 100 to 102, wherein the reflective surface comprises a diffractive element.
104. The metrology or inspection apparatus of any one of clauses 88 to 99, wherein the surface is a surface of a filtering device.
105. The metrology or inspection apparatus of any one of clauses 88 to 99, wherein the filtering device comprises a Zirconium film.

While specific embodiments of the invention have been described above, it will be appreciated that the invention may be practiced otherwise than as described.

The descriptions above are intended to be illustrative, not limiting. Thus, it will be apparent to one skilled in the art that modifications may be made to the invention as described without departing from the scope of the claims set out below.

1.-20. (canceled)

21. A lithographic apparatus comprising:
an enclosure defining an environment, wherein the environment encompasses a surface, wherein the enclosure is configured to contain plasma;
a microwave generator configured to provide microwave radiation into the enclosure;
a magnetic source configured to generate a magnetic field adjacent the surface that, together with the microwave radiation, generates plasma by electron cyclotron resonance, thereby increasing the concentration of plasma adjacent the surface.

22. The lithographic apparatus of claim 21, wherein:
the microwave generator is located outside the environment; and
the enclosure is configured to contain a base concentration of plasma resulting from EUV radiation.

23. The lithographic apparatus of claim 21, wherein the enclosure is configured to contain hydrogen gas.

24. The lithographic apparatus of claim 21, wherein the plasma comprises hydrogen plasma.

25. The lithographic apparatus of claim 21, wherein the magnetic source comprises a permanent magnet and/or an electromagnet.

26. The lithographic apparatus of claim 21, wherein the magnetic source comprises a plurality of permanent magnets and/or a plurality of electromagnets.

27. The lithographic apparatus of claim 21, wherein the magnetic source is shielded from the plasma.

28. The lithographic apparatus of claim 21, wherein the magnetic source is located outside the enclosure.

29. The lithographic apparatus of claim 21, further comprising a waveguide configured to guide the microwave radiation from the microwave generator into the enclosure.

30. The lithographic apparatus of claim 21, configured to prevent the plasma from flowing along a straight line between the surface and a microwave window through that the microwave radiation from the microwave generator travels into the enclosure.

31. The lithographic apparatus of claim 21, wherein the microwave generator is configure to be replaced while the lithographic apparatus is operating to manufacture devices.

32. The lithographic apparatus of claim 21, wherein the surface comprises a surface within an EUV laser-produced plasma source vessel.

33. The lithographic apparatus of claim 32, wherein the surface comprises the surface of a collector mirror within the vessel.

34. The lithographic apparatus of claim 33, wherein the magnetic source comprises a magnetic source embedded in the collector mirror.

35. The lithographic apparatus of claim 32, wherein the surface comprises an inner wall of the vessel.

36. The lithographic apparatus of claim 32, wherein the vessel comprises an exhaust, and the microwave radiation is provided into the vessel via the exhaust.

37. The lithographic apparatus of claim 21, wherein the surface comprises a window for metrology.

38. The lithographic apparatus of claim 37, wherein the magnetic source comprises a magnetic source embedded in the window.

39. The lithographic apparatus of claim 21, wherein the surface comprises the optical surface of a MEMS mirror device.

40. A method comprising:
providing, by a microwave generator, microwave radiation into an enclosure, wherein the enclosure defines an environment in a lithographic apparatus, and the environment encompasses a surface; and
generating, by a magnetic source, a magnetic field adjacent the surface that, together with the microwave radiation, generates plasma by electron cyclotron resonance, thereby increasing the concentration of plasma adjacent the surface.
